(19) United States
(12) Patent Application Publication
(10) Pub. No.: US 2026/0109466 A1
(43) Pub. Date: Apr. 23, 2026

(54) PROPULSION ASSEMBLY COMPRISING AT LEAST ONE PROTECTIVE HOUSING CONFIGURED TO ACCOMMODATE AT LEAST A PORTION OF AN ELONGATED ELEMENT SUCH AS AN ELECTRIC CABLE

(71) Applicant: Airbus Operations SAS, TOULOUSE (FR)

(72) Inventors: Jacky PUECH, TOULOUSE (FR); Solène CRUAUD-PRIEUR, TOULOUSE (FR); Fabien POUSSOU, TOULOUSE (FR); Jérôme NENY, TOULOUSE (FR)

(21) Appl. No.: 19/351,990

(22) Filed: Oct. 7, 2025

(30) Foreign Application Priority Data
Oct. 18, 2024 (FR) FR2411302

(51) Int. Cl. B64D 29/06; B64D 27/40; F02C 7/20; F02C 7/25; H05K 5/02

(52) U.S. Cl. CPC B64D 29/06; B64D 27/402; F02C 7/20; H05K 5/0209; H05K 5/0213; H05K 5/0247; F02C 7/25; F05D 2220/323; F05D 2240/14

(57) ABSTRACT

A propulsion assembly with a propulsion unit, a primary structure of a pylon configured to connect the propulsion unit to an aircraft structure, at least one elongated element selected from among an electric cable, a duct, and a sheath, which extends from the primary structure to the propulsion unit, and at least one thermally insulated protective housing, separate from the primary structure, delimiting an internal zone that extends from the primary structure to as close as possible to the propulsion unit, and in which the elongated element is positioned.

### CROSS-REFERENCES TO RELATED APPLICATIONS

This application claims the benefit of French Patent Application Number FR2411302 filed on Oct. 18, 2024, the entire disclosure of which is incorporated herein by way of reference.

### FIELD OF THE INVENTION

The present application relates to a propulsion assembly comprising at least one protective housing configured to accommodate at least a portion of an elongated element such as an electric cable, and also to an aircraft including at least one propulsion assembly of this kind.

### BACKGROUND OF THE INVENTION

According to a configuration shown in FIGS. 1 to 3, an aircraft 10 comprises several propulsion assemblies 12 that are positioned beneath the wing 14 of the aircraft 10.

A propulsion assembly 12 comprises a propulsion unit 16, a nacelle 18 (not shown in FIG. 2) positioned around the propulsion unit 16, and a pylon 20 connecting the propulsion unit 16 to the rest of the aircraft 10, particularly to the wing 14.

For the remainder of the description, a longitudinal direction X is parallel to the axis of rotation A16 of the propulsion unit 16. A transverse plane is a plane perpendicular to the axis of rotation A16 of the propulsion unit 16. A transverse and horizontal direction Y is a direction perpendicular to the axis of rotation A16 of the propulsion unit 16 and horizontal. A transverse and vertical direction Z is a direction perpendicular to the axis of rotation A16 of the propulsion unit 16 and vertical. A vertical median plane PMV is a vertical plane containing the axis of rotation A16 of the propulsion unit 16. The terms “front” and “rear” refer to the direction of airflow through the propulsion unit 16, the airflow moving from front to rear.

The propulsion unit 16 comprises a fan 22 that includes a fan casing 22.1, as well as a core engine 24 that extends from a front portion 24.1 located inside the fan 22 to a rear portion 24.2. The core engine 24 has an outer casing referred to as the engine casing F24.

The nacelle 18 comprises an inner wall 18.1 which, together with the engine casing F24, defines an annular duct 26 through which an airflow passes.

The propulsion assembly 12 also comprises upper and lower bifurcations, positioned at 12 o'clock and 6 o'clock, respectively, connecting the inner wall 18.1 of the nacelle to the propulsion unit 16. Each upper and lower bifurcation is hollow and forms a housing in which equipment can be positioned.

The pylon 20 comprises a primary structure 28, in the form of a box, which is connected to the wing 14 by a wing attachment system and to the propulsion unit 16 by an engine attachment system. This primary structure 28 comprises a lower wall 28.1, oriented toward the propulsion unit 16, which acts as a fire barrier.

According to an embodiment shown in FIG. 2, the engine attachment system comprises a front attachment 30.1 connecting the front end of the primary structure 28 to the fan casing 22.1, a rear attachment 30.2 connecting the rear end of the primary structure 28 to the rear portion 24.2 of the core engine 24, and two links 30.3, positioned symmetrically with respect to the vertical median plane PMV of the propulsion unit 16, connecting the primary structure 28 to the core engine 24.

As illustrated in FIG. 3, electric cables 32, and optionally piping, run through the upper bifurcation between the primary structure 28 of the pylon 20 and the propulsion unit 16. These electric cables 32 must be protected from high temperatures (well above 200° C.), particularly in the area located beneath the lower wall 28.1 of the primary structure 28, which is a so-called fire zone. To this end, each cable comprises a protective sheath that thermally insulates it from high temperatures. This embodiment is unsatisfactory because it leads to an increase in both the mass of the electric cables 32 and their bulk.

### SUMMARY OF THE INVENTION

The present invention aims to overcome all or some of the disadvantages of the prior art.

To this end, the object of the invention is a propulsion assembly comprising:
a propulsion unit,
a nacelle surrounding the propulsion unit,
an annular duct positioned between the propulsion unit and the nacelle,
at least one upper bifurcation extending into the annular duct and connecting the nacelle and the propulsion unit,
a primary structure of a pylon configured to connect the propulsion unit to an aircraft structure,
at least one elongated element selected from among an electric cable, a duct, and a sheath, which extends through the bifurcation and from the primary structure to the propulsion unit.

According to the invention, the propulsion assembly comprises at least one thermally insulated protective housing, separate from the primary structure, delimiting at least a portion of an internal zone that extends from the primary structure to as close as possible to the propulsion unit, and in which the elongated element is positioned.

According to the invention, since the portion of the elongated element located within the protective housing is protected, only a reduced section of the elongated element, located between the protective housing and the propulsion unit, needs to be protected, which helps to reduce the weight and the bulk of the elongated element.

According to another feature, the protective housing comprises at least one air inlet that provides communication between an external area of the protective housing located in the annular duct and the internal area of the protective housing. According to another feature, the upper bifurcation comprises a leading edge at which the air inlet is located.

According to another feature, the protective housing comprises at least one exhaust outlet allowing air to exit the protective housing.

According to another feature, the protective housing comprises:
at least one passage wall, spaced a short distance from the propulsion unit, including at least one through-hole through which the elongated element passes,
at least one sealing system, located at each through-hole, configured to fill a gap between the passage wall and the elongated element.

According to another feature, the protective housing exhibits a front transverse wall, a rear transverse wall, a substantially horizontal end wall connecting the front and rear transverse walls, and right and left side walls connected to the end wall and to the front and rear transverse walls.

According to another feature, the rear transverse wall comprises an upper edge connected to the primary structure in a sealing manner.

According to another feature, the front transverse wall exhibits an upper edge spaced apart from the primary structure, the propulsion assembly comprising at least one partition connected in a sealing manner to the front transverse wall and to the upper bifurcation.

According to another feature, the right and left side walls have upper edges spaced apart from the primary structure, the propulsion assembly comprising, for each of the right and left side walls, at least one sealing gasket interposed between the right or left side wall and the upper bifurcation.

According to another feature, the propulsion assembly comprises a first sealing gasket interposed between, on the one hand, an upper edge of the right side wall, a right edge of the rear transverse wall and a right edge of the primary structure, and, on the other hand, the upper bifurcation, and a second sealing gasket interposed between, on the one hand, an upper edge of the left side wall, a left edge of the rear transverse wall, and a left edge of the primary structure, and, on the other hand, the upper bifurcation.

According to another feature, each of the right and left side walls includes a first section adjacent to the end wall and inclined so as to be oriented toward the propulsion unit, and a second section forming an angle of between 60°and 120° with the first section.

According to another feature, the protective housing is suspended beneath the primary structure, the propulsion assembly comprising at least one connecting rod that connects the protective housing to the primary structure.

The invention also relates to an aircraft comprising at least one propulsion assembly according to any of the preceding features.

### BRIEF DESCRIPTION OF THE DRAWINGS

Further features and advantages will become apparent from the following description of the invention, provided solely by way of example and with reference to the appended drawings, in which:

FIG. 1 is a side view of an aircraft,

FIG. 2 is a side view of a propulsion assembly without a nacelle illustrating an embodiment of the prior art,

FIG. 3 is a schematic representation of a portion of a propulsion assembly illustrating an embodiment of the prior art,

FIG. 4 is a schematic representation of a portion of a propulsion assembly illustrating an embodiment of the invention,

FIG. 5 is a side view of a protective housing illustrating an embodiment of the invention,

FIG. 6 is a perspective view of a bifurcation of a propulsion assembly at which a protective housing is positioned, illustrating an embodiment,

FIG. 7 is a longitudinal section of a portion of the bifurcation shown in FIG. 6,

FIG. 8 is a perspective view of a protective housing illustrating an embodiment of the invention,

FIG. 9 is a longitudinal section of the protective housing shown in FIG. 8.

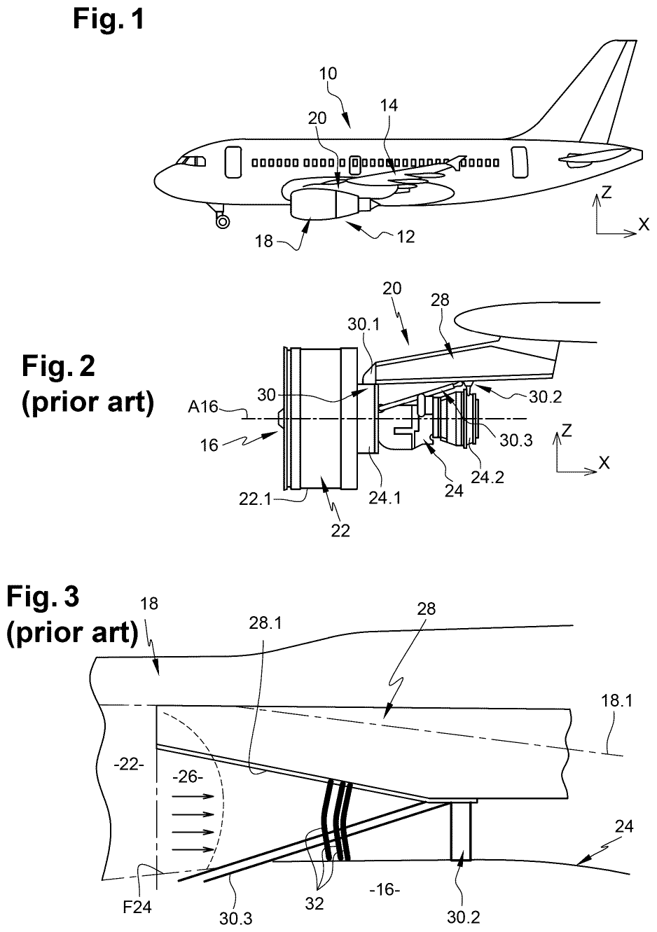

### DETAILED DESCRIPTION OF THE PREFERRED EMBODIMENTS

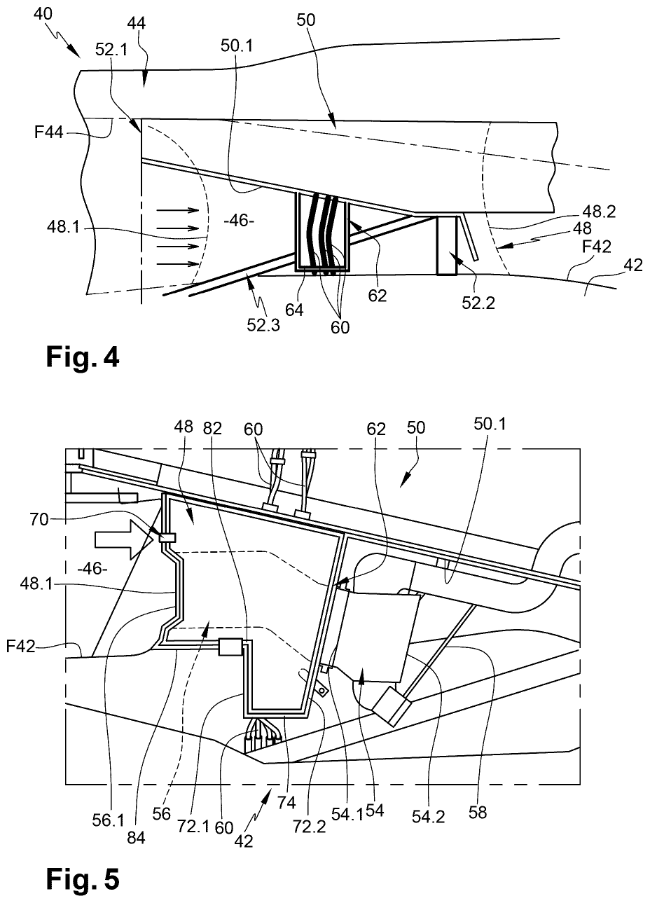

According to an embodiment shown in FIG. 4, a propulsion assembly 40 comprises a propulsion unit 42, a nacelle 44 positioned around the propulsion unit 42, and a pylon connecting the propulsion unit 42 to an aircraft structure, such as an aircraft wing, for example.

The propulsion unit 42 comprises an outer casing F42. Additionally, the nacelle 44 includes an inner wall F44, which, together with the outer casing F42 of the propulsion unit 42, defines an annular duct 46 located between the nacelle 44 and the propulsion unit 42, through which an airflow passes.

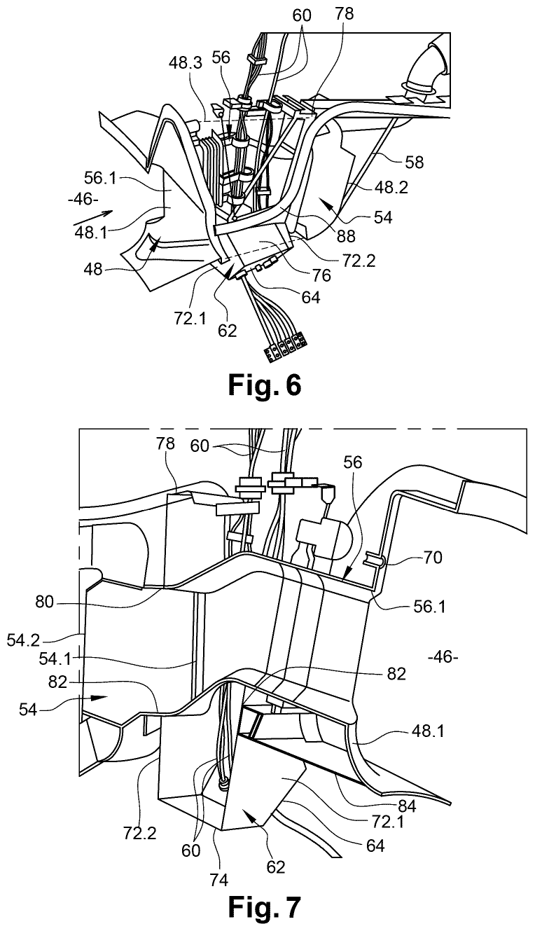

The propulsion assembly 40 comprises at least one upper bifurcation 48, positioned at 12 o'clock, which extends into the annular duct 46 and connects the inner wall F44 of the nacelle 44 to the propulsion unit 42. Generally speaking, the propulsion assembly 40 also comprises a lower bifurcation positioned at 6 o'clock. The upper bifurcation 48 is hollow and forms a housing in which equipment, ducts, electric cables, and other components, may be positioned. According to an embodiment shown in FIG. 6, the upper bifurcation 48 forms an aerodynamic fairing and includes a leading edge 48.1, a trailing edge 48.2, and lateral walls 48.3 connecting the leading and trailing edges 48.1, 48.2, which are substantially (+/−10%) symmetrical in relation to the vertical median plane PMV. In FIG. 6, only one of the lateral walls 48.3 is represented in dashed lines.

The pylon comprises a primary structure 50 configured to connect the propulsion unit 42 to an aircraft structure, such as a wing, for example. This primary structure 50 is connected to the propulsion unit 42 by an engine attachment system and generally has a box structure. This primary structure 50 includes a lower wall 50.1 oriented toward the propulsion unit 42 and configured to form a fire barrier. In one arrangement, a portion of the primary structure 50 is positioned within the upper bifurcation 48.

According to one embodiment, the engine attachment system may include a front attachment 52.1 connecting the front end of the primary structure 50 to the propulsion unit 42, a rear attachment 52.2 connecting the rear end of the primary structure 50 to the propulsion unit 42, and two links 52.3, positioned symmetrically with respect to the vertical median plane PMV of the propulsion unit 42, connecting the primary structure 50 to the propulsion unit 42.

The propulsion unit 42, the nacelle 44, the upper and lower bifurcations 48, the primary structure 50 of the pylon, and the engine attachment system are not described in greater detail, as they are known to a person skilled in the art and may be substantially identical to those of the prior art. Whatever the embodiment, an aircraft comprises at least one propulsion assembly 40.

The propulsion assembly 40 comprises at least one heat exchanger 54 positioned between the primary structure 50 and the propulsion unit 42 inside the upper bifurcation 48, said heat exchanger 54 being configured to ensure thermal exchanges between two fluids. This heat exchanger 54 comprises a first inlet 54.1, oriented toward the leading edge 48.1 of the upper bifurcation 48, allowing a first fluid to enter the heat exchanger 54, and a first outlet 54.2, oriented toward the trailing edge 48.2, allowing the first fluid to exit the heat exchanger 54.

In one arrangement, the heat exchanger 54 is positioned close to the trailing edge 48.2 of the upper bifurcation 48. Additionally, the propulsion assembly 40 comprises a line 56, positioned in the upper bifurcation 48, which connects a through-opening 56.1 provided at the leading edge 48.1 of the upper bifurcation 48 and the first inlet 54.1 of the heat exchanger 54. Naturally, the invention is not limited to this arrangement for the heat exchanger 54.

According to one embodiment, the heat exchanger 54 is fixed to the primary structure 50. For example, the heat exchanger 54 is suspended beneath the primary structure 50 and connected to it by connecting rods 58.

The propulsion assembly 40 comprises at least one electric cable 60 running from the nacelle 44 to the propulsion unit 42. In one configuration, the electric cable 60 is positioned inside the upper bifurcation 48 and extends from the lower wall 50.1 of the primary structure 50 to the propulsion unit 42.

In one arrangement, the propulsion assembly 40 comprises several electric cables 60 grouped into one or more electric cable harnesses.

In a particular aspect of the invention, the propulsion assembly 40 comprises at least one thermally insulated protective housing 62 positioned between the primary structure 50 and the propulsion unit 42, in which is located at least one electric cable 60 that runs from the nacelle 44 to the propulsion unit 42. The protective housing 62 comprises at least one passage wall 64 positioned close to the propulsion unit 42 through which the electric cable 60 passes. “Positioned close” means that the passage wall 64 is spaced apart from the propulsion unit 42, more specifically from its outer casing F42, by a distance of less than 20 cm and preferably less than 10 cm.

This protective housing 62 is separate from the primary structure 50 and configured to form a fire barrier. As an example, this protective housing 62 is made of stainless steel, TA6V titanium, or an alloy resistant to relatively high temperatures.

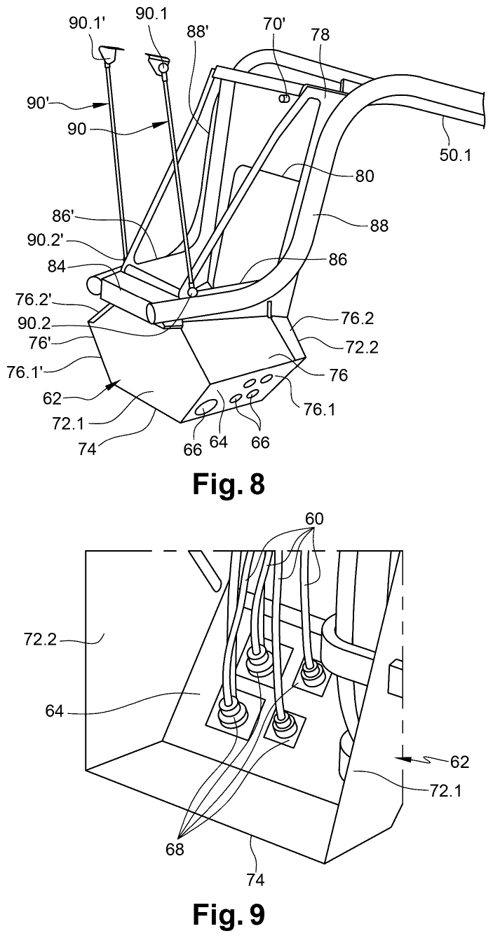

The passage wall 64 comprises at least one through-hole 66 (visible in FIG. 8) to accommodate at least one electric cable 60 and allow it to pass through the passage wall 64. In order to achieve sealing between the passage wall 64 and each electric cable 60 passing through it, the protective housing 62 comprises at least one sealing system 68, such as a cable gland (visible in FIG. 9), at each through-hole 66, configured to fill a space between the passage wall 64 and the electric cable 60.

This protective housing 62 comprises at least one air inlet 70 that provides communication between an exterior area located outside the protective housing 62 and within the annular duct 46, and an interior area located inside the protective housing 62. This air inlet 70 allows fresh air flowing through the annular duct 46 to enter the inside of the protective housing 62, in order to ventilate the interior of the protective housing 62 and limit a temperature rise within the protective housing 62. For reference, the fresh air entering the protective housing 62 at a temperature of around 100° C. allows the temperature inside the protective housing 62 to be maintained below 200° C., clearly lower than the temperature of the air surrounding the protective housing 62 on the outside thereof, which may reach approximately 500° C.

According to one configuration, the air inlet 70 is located at the leading edge 48.1 of the bifurcation 48. Hence, when the propulsion unit 42 is operating, the air flowing through the annular duct 46 naturally enters the protective housing 62.

In addition to the air inlet 70, the protective housing 62 comprises an exhaust outlet 70′ that allows the air inside the protective housing to exit said housing. The air inlet 70 and the exhaust outlet 70′ are arranged in such a manner as to promote ventilation throughout all the internal regions of the protective housing 62.

In one arrangement, the protective housing 62 exhibits a front transverse wall 72.1 (perpendicular to the longitudinal direction X), a rear transverse wall 72.2 parallel to the front transverse wall 72.1 and offset toward the rear in respect of said transverse wall, a substantially horizontal end wall 74 connecting the front and rear transverse walls 72.1, 72.2, and right and left side walls 76, 76′ connected to the end wall 74 and connecting the front and rear transverse walls 72.1, 72.2.

According to one configuration, the right and left side walls 76, 76′ are not vertical. Each right and left side wall 76, 76′ comprises a first section 76.1, 76.1′ adjacent to the end wall 74 and inclined to form (from the inside of the protective housing 62) an angle greater than 110° with the end wall 74, so that it is oriented toward the propulsion unit 42, and a second section 76.2, 76.2′ forming an angle of between 60° and 120° with the first section 76.1, 76.1′.

In this configuration, at least one of the elements among the first sections 76.1, 76.1′ of the right and left side walls 76, 76′ and the end wall 74 may constitute a passage wall 64 through which the electric cable(s) 60 pass(es).

According to one embodiment, the rear transverse wall 72.2 is nearly abutted against the heat exchanger 54 and extends up to the primary structure 50. Accordingly, it comprises an upper edge 78 connected in a sealing manner to the primary structure 50, as well as an opening 80 to allow the passage of the line 56 that supplies the heat exchanger 54. In this embodiment, the rear transverse wall 72.2 is connected in a sealing manner to the primary structure 50 and to the line 56. This rear transverse wall 72.2 includes the exhaust outlet 70′ that allows air to exit the protective housing 62.

In one arrangement, the front transverse wall 72.1 has an upper edge 82 spaced from the primary structure 50. In this case, the propulsion assembly comprises at least one substantially horizontal partition 84 connected in a sealing manner to the front transverse wall 72.1 and to the upper bifurcation 48. Likewise, the right and left side walls 76, 76′ have upper edges 86, 86′ spaced apart from the primary structure 50. In this arrangement, a portion of the upper bifurcation 48 ensures continuity between the protective housing 62 and the primary structure 50 and/or the nacelle 44. Hence, the protective housing 62 and a portion of the upper bifurcation 48 define a ventilated cavity in which a temperature below 200° C. is maintained. In this arrangement, the propulsion assembly comprises, for each of the right and left side walls 76, 76′, at least one sealing gasket 88, 88′ interposed between the right or left side wall 76, 76′ and the upper bifurcation 48. The latter ensures continuity between, on one hand, the partition 84 and the upper edges 86, 86′ of the right and left side walls 76, 76′ and, on the other hand, the primary structure 50 and/or the nacelle 44. According to one embodiment, at least one sealing gasket 88 is provided between the bifurcation 48 and at least one element among the upper edges 86, 86′ of the right and left side walls 76, 76′, the partition 84, and the rear transverse wall 72.2. According to one configuration, a first sealing gasket 88 is interposed between, on one the one hand, the right edge of the partition 84, the upper edge 86 of the right side wall 76, and the right edge of the rear transverse wall 72.2, and, on the other hand, the bifurcation 48. This first sealing gasket 88 may extend up to the right edge of the lower wall 50.1 of the primary structure 50. Additionally, a second sealing gasket 88′ is interposed between, on one hand, the left edge of the partition 84, the upper edge 86′ of the left side wall 76′, and the left edge of the rear transverse wall 72.2, and, on the other hand, the bifurcation 48. This second sealing gasket 88′ may extend up to the left edge of the lower wall 50.1 of the primary structure 50.

In one embodiment, the protective housing 62 is suspended beneath the primary structure 50, and the propulsion assembly 40 comprises at least one connecting rod 90 connecting the protective housing 62 to the primary structure 50. In one configuration, the upper edge 78 of the rear transverse wall 72.2 is fixed to the primary structure 50. Additionally, the propulsion assembly 40 comprises a first connecting rod 90 that comprises a first end 90.1 connected to the primary structure 50 and a second end 90.2 connected to the upper edge 86 of the right side wall 76 at a point as far as possible away from the rear transverse wall 72.2, as well as a second connecting rod 90′ that comprises a first end 90.1′ connected to the primary structure 50 and a second end 90.2′ connected to the upper edge 86′ of the left side wall 76′ at a point as far as possible away from the rear transverse wall 72.2. The invention is of course not limited to this embodiment for connecting the protective housing 62 to the nacelle 44 and/or to the primary structure 50.

Regardless of the embodiment, the propulsion assembly 40 comprises at least one elongated element, selected from among an electric cable 60, a duct, and a sheath, which extends through the upper bifurcation 48, from the primary structure 50 to the propulsion unit 42, as well as at least one thermally insulated protective housing 62 that defines at least a portion of an internal zone in which the elongated element is positioned, said internal zone extending from the primary structure 50 of the pylon to as close as possible to the propulsion unit 42, a temperature below 200° C. being maintained in said internal zone. Thus, the elongated element—i.e., the electric cable 60, duct and/or sheath—does not need to be fire-rated along the section located within the protective housing 62, which allows the weight of the elongated element to be reduced.

According to a preferred configuration, the propulsion assembly 40 comprises a ventilation system for the internal zone of the protective housing 62, in order to maintain a temperature below 200° C. therein, said ventilation system comprising at least one air inlet 70 configured to draw air from the annular duct 46 and direct it into the protective housing 62, as well as an exhaust outlet 70′ allowing air from within the protective housing 62 to be discharged.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

1. A propulsion assembly comprising:
a propulsion unit;
a nacelle surrounding the propulsion unit;
an annular duct positioned between the propulsion unit and the nacelle;
at least one upper bifurcation extending into the annular duct and connecting the nacelle and the propulsion unit;
a primary structure of a pylon configured to connect the propulsion unit to an aircraft structure;
at least one elongated element extending through the at least one upper bifurcation and from the primary structure to the propulsion unit, the at least one elongated element selected from a group consisting of: an electric cable; a duct; and a sheath; and,
at least one thermally insulated protective housing, separate from the primary structure, delimiting at least a portion of an internal zone that extends from the primary structure to, as close as possible, the propulsion unit, and in which the at least one elongated element is positioned.

2. The propulsion assembly as claimed in claim 1, wherein the at least one thermally insulated protective housing comprises at least one air inlet that provides communication between an external area of the at least one thermally insulated protective housing located in the annular duct and an internal area of the at least one thermally insulated protective housing.

3. The propulsion assembly as claimed in claim 2, wherein the at least one upper bifurcation comprises a leading edge at which the air inlet is located.

4. The propulsion assembly as claimed in claim 1, wherein the at least one thermally insulated protective housing comprises at least one exhaust outlet allowing air to exit the at least one thermally insulated protective housing.

5. The propulsion assembly as claimed in claim 1, wherein the at least one thermally insulated protective housing comprises:
at least one passage wall, spaced from the propulsion unit and including at least one through-hole through which the at least one elongated element passes; and,
at least one sealing system, located at the at least one through-hole and configured to fill a gap between the at least one passage wall and the at least one elongated element.

6. The propulsion assembly as claimed in claim 1, wherein the at least one thermally insulated protective housing comprises a front transverse wall, a rear transverse wall, a substantially horizontal end wall connecting the front transverse wall and the rear transverse wall, and a right side wall and a left side wall connected to the end wall and to the front transverse wall and the rear transverse wall.

7. The propulsion assembly as claimed in claim 6, wherein the rear transverse wall comprises an upper edge connected to the primary structure in a sealing manner.

8. The propulsion assembly as claimed in claim 6, wherein the front transverse wall comprises an upper edge spaced apart from the primary structure, and
wherein the propulsion assembly further comprises at least one partition connected in a sealing manner to the front transverse wall and to the upper bifurcation.

9. The propulsion assembly as claimed in claim 6, wherein the right and left side walls have upper edges spaced apart from the primary structure, and
wherein the propulsion assembly further comprises, for each of the right and left side walls, at least one sealing gasket interposed between the right and left side wall, respectively, and the at least one upper bifurcation.

10. The propulsion assembly as claimed in claim 6, further comprising:
a first sealing gasket interposed between: an upper edge of the right side wall, a right edge of the rear transverse wall, and a right edge of the primary structure, and the upper bifurcation, and a second sealing gasket interposed between: an upper edge of the left side wall, a left edge of the rear transverse wall, and a left edge of the primary structure, and, the upper bifurcation.

11. The propulsion assembly as claimed in claim 6, wherein the right and left side walls each include a first section adjacent to the end wall and inclined so as to be oriented towards the propulsion unit, and a second section forming an angle of between 60 and 120° with the first section.

12. The propulsion assembly as claimed in claim 1, wherein the at least one thermally insulated protective housing is suspended beneath the primary structure, and
wherein the propulsion assembly further comprises at least one connecting rod that connects the protective housing to the primary structure.

13. An aircraft comprising:
at least one propulsion assembly as claimed in claim 1.
